(19) United States
(12) Patent Application Publication
(10) Pub. No.: US 2017/0349788 A1
(43) Pub. Date: Dec. 7, 2017

(54) POLYDISPERSE LARGE-PARTICLE-SIZE SILICA SOL AND METHOD OF PREPARING THE SAME

(71) Applicants: Shanghai Xinanna Electronic Technology Co., LTD, Shanghai (CN); Shanghai Institute of Microsystem and Information Technology, Chinese Academmy of Sciences, Shanghai (CN)

(72) Inventors: Hui Kong, Shanghai (CN); Weili Liu, Shanghai (CN); Zhitang Song, Shanghai (CN)

(73) Assignees: Shanghai Xinanna Electronic Technology Co., LTD, Shanghai (CN); Shanghai Institute of Microsystem and Information Technology, Chinese Academy of Sciences, Shanghai (CN)

(21) Appl. No.: 15/219,533

(22) Filed: Jul. 26, 2016

(30) Foreign Application Priority Data
Jun. 1, 2016 (CN) 201610382474.6

(51) Int. Cl. C09G 1/02; C09K 3/14; C01B 33/145; H01L 21/306

(52) U.S. Cl. CPC C09G 1/02; H01L 21/30625; C09K 3/1463; C01B 33/145; C01P 2004/03; C01P 2004/64

(57) ABSTRACT

The present disclosure provides a polydispersion large-particle-size silica sol and a method of preparing the same. The polydispersion large-particle-size silica sol is mainly used as a polishing solution to enhance a polishing rate. The preparing method prepares the silica sol by stirring and heating a monodisperse spherical silica sol with a particle size of 20 nm-30 nm which is taken as a seed crystal, and meanwhile constantly adding, by drops, the seed crystal of the monodisperse spherical silica sol with a particle size of 20 nm-30 nm and active silicic acid into a reaction system, wherein during the whole reaction process, a heating concentration method is adopted to maintain a constant liquid level and during this period, inorganic dilute alkali solution is added by drops to maintain the pH value of the system between 9.5 and 10.5; cooling is performed after heat preservation. With the silica sol prepared according to the present disclosure, the polishing rate can be effectively enhanced, and meanwhile, occurrences of scratches can be reduced.

### BACKGROUND OF THE DISCLOSURE

With the advancement of integrated circuit technologies, it becomes increasingly demanding on surface quality of a substrate material in use. Due to the diminishing of device size and reduction of focal depth of an optical lithography device, it is required that the flatness of an acceptable resolution of the wafer surface should reach the nanometer level. In order to solve this problem, the CMP (Chemical Mechanical Polishing) that can implement global planarization becomes one of key technologies for semiconductor manufacturing. Current polishing solution products mainly use a monodisperse silicon oxide as a grinding material. Traditionally, there are two kinds of silicon oxide grinding materials: sintered silicon oxide and colloidal silicon oxide. The sintered silicon oxide has a fast polishing rate, but the polished material has a poor surface quality with serious scratches; the colloidal silicon oxide has a good surface quality but a slow polishing rate. Thus, it is a great challenge for the CPM polishing solution to enhance the polishing rate without compromising the surface quality. In order to overcome the drawbacks in the prior art, many scientific workers have made some beneficial attempts, e.g., preparing aspherical silicon oxide particles. In the Patent CN101626979A, there are provided elongated silicon oxide particles and a method of preparing the same, which has a high friction coefficient and polishing rate when polishing. Preparation of the aspherical silicon oxide particles will generally introduce a bivalent or trivalent metal salt solution, which will degrade the stability of a silica sol system; or an organic alkali solution is used during the preparing process, while the organic alkali is hard to be removed from the silica sol system and easily causes environmental pollution.

### SUMMARY OF THE DISCLOSURE

In view of the above drawbacks in the prior art, an objective of the present disclosure is to provide a polydisperse large-particle-size silica sol and a method of preparing the silica sol. The silica sol has a wide particle size distribution; when polishing a semiconductor material, the large-particle-size silica sol cooperates with small-particle-size silica sol, which boosts a large friction coefficient, a strong chemical activity, and a high polishing efficiency. It has been tested that the using of the silica sol of the present disclosure may enhance the polishing rate by 37% or above, with fewer scratches occurring on a polished wafer.

In order to achieve the above and other relevant objectives, the present disclosure provides a method of preparing a polydisperse large-particle-size silica sol, wherein the polydispersion means the silica sol is not distributed with a single particle size, but in a mixed state of a plurality of particle sizes. Herein, the difference between maximal particle size and minimal particle size amounts to 75 nm and the particle sizes are distributed between 20 nm and 95 nm; the large-particle-size means the particle size of the silica sol reaches 20 nm above.

The preparing method comprises: stirring and heating a monodisperse spherical silica sol having a particle size between 20 nm-30 nm as a crystal seed, and meanwhile constantly dropping the monodisperse spherical silica sol crystal seed with a particle size between 20 nm-30 nm and active silicic acid into a reaction system; during a whole reaction procedure, maintaining a constant liquid level by using a heating concentration method and meanwhile dropping inorganic dilute alkali solution to maintain a pH value of the system between 9.5 and 10.5; preserving the temperature upon end of the reaction, and cooling it.

Step (1) of preparing active silicic acid: dilute concentrated water glass using water to a solution with a silicon oxide content of 2-6 wt %; after the solution is stirred evenly, add the solution into a strong acid-type cation exchange resin for cation exchanging to obtain an active silicic acid with a pH between 2.0 and 4.0.

Step (2) of preparing a monodisperse small-particle-size silica sol crystal seed: take an inorganic alkali solution of 0.1-1.0 wt %, stir and heat the solution to 90-100° C. gradually add the active silicic acid prepared in the step (1) with a volume 2-4 times than the inorganic alkali solution; after the addition process is completed, preserve the temperature, and naturally cool it to the room temperature to obtain the monodisperse spherical silica sol with a particle size between 20 nm and 30 nm as the crystal seed.

Preferably, the duration for which the temperature is preserved is in a range of 0.5-2 hours.

Preferably, the adding speed at which the active silicic acid is added is in a range of 2-20 ml/min.

Step (3) of preparing polydisperse large-particle-size silica sol: take the crystal seed prepared in step (2) as mother solution; stir and heat the solution to be boiled; then add the active silicic acid prepared in the step (1) into the reaction system with a rate of 4-10 ml/min; meanwhile, continuously and constantly supplement the crystal seed prepared in the step (2) into the reaction system at a rate of 0.85-1.85 ml/min; maintain a constant liquid level and meanwhile drop the inorganic alkali solution to maintain the pH value of the whole system at 9.50-10.50; upon completion of the addition, continue to preserve temperature, and naturally cool it to the room temperature.

Preferably, a duration for which the temperature preservation is 0.5-2 hours.

Preferably, the polydisperse large-particle-size silica sol has a particle size of 20 nm-95 nm.

### BRIEF DESCRIPTION OF THE ACCOMPANYING DRAWINGS

FIG. 1 illustrates an electron microscope image of a polydisperse large-particle-size silica sol prepared according to Example 1.

FIG. 2 illustrates an electron microscope image of a polydisperse large-particle-size silica sol prepared according to Example 2.

FIG. 3 illustrates an electron microscope image of a polydisperse large-particle-size silica sol prepared according to Example 3.

### DETAILED DESCRIPTION OF THE PREFERRED EMBODIMENTS

Hereinafter, the embodiments of the present disclosure will be illustrated through specific instances. Those skilled in the art may easily understand that other advantages and effects of the present disclosure from the disclosure of the specification. The present disclosure may also be implemented or applied through other different concrete embodiments. Various details in the present description may also be modified or changed based on different views or applications without departing from the spirit of the present disclosure. It should be noted that in the following examples, processing devices or means not explicitly labeled all adopt conventional devices or means in the art. Besides, it should also be understood that one or more method steps as mentioned in the present disclosure do not exclude existence of other method steps before and after the combining step, or other method steps may also be inserted between these explicitly mentioned steps, unless otherwise explained. Moreover, unless otherwise indicated, serial numbers of respective steps are only for facilitating discrimination between respective method steps, not arrangement order for limiting respective method steps or limiting the implementable scope of the present disclosure; change or adjustment of their relative relationships should also be regarded as implementable scope of the present disclosure without substantively changing the technical content.

The electron microscope used for observing the silica sol in the following examples is a focused ion beam system modeled Helios NanoLab 600, manufactured by the FEI company from the USA.

### Example 1: Polydisperse Large-Particle-Size Silica Sol and Method of Preparing the Same

Step (1): Dilute concentrated water glass with pure water to a 4% content of silicon oxide; stir it evenly, and add it into a strong acid-type cation exchange resin (polyphenyl sulfonic acid-type) that has been subject to regeneration processing, for cation exchanging, so as to obtain an active silicic acid with a pH value of 2.85 and 4% content of the silicon oxide.

Step (2): take 1 wt % potassium hydroxide solution with a volume of 1000 ml, stir and heat it to 98° C.; pump 4000 ml of the active silicic acid prepared in step (1) through a peristaltic pump at a rate of 8 ml/min. After the addition of the active silicic acid is completed, preserve the temperature for 0.5 hours. Naturally cool it to the room temperature and thereby obtain a monodisperse spherical silica sol with a particle size of 20 nm-30 nm as a crystal seed.

Step (3), weigh 800 ml of the crystal seed prepared in step (2) as mother solution, stir and heat the solution to be boiled; add the active silicic acid prepared in step (1) at a 6.5 ml/min, and meanwhile continuously supplement 2760 ml of the crystal seed prepared in step (2) through the peristaltic pump at a rate of 0.92 ml/min; during this period of time, drop a 1 wt % potassium hydroxide diluted solution to the mother solution to maintain the pH value of the whole system between 9.50 and 10.50. After the reaction was completed, preserve the temperature at 100° C. for 2 hours; naturally cool it to the room temperature, thereby obtaining the polydisperse large-particle-size silica sol spherical silica sol.

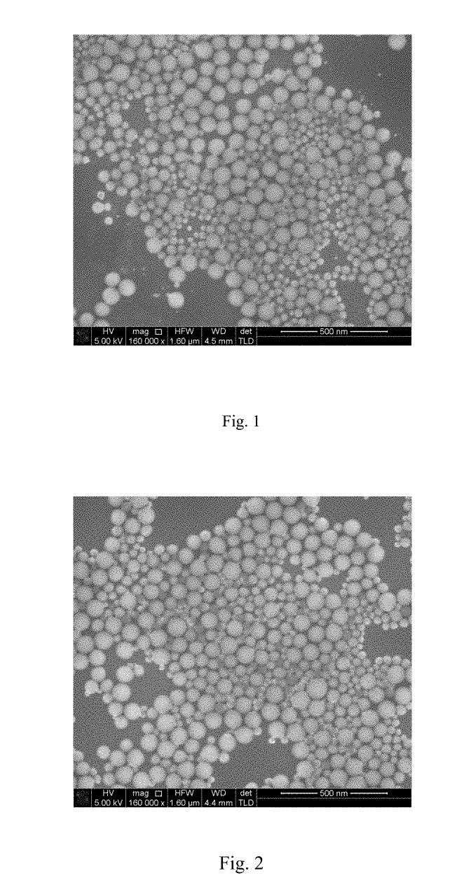

As illustrated in FIG. 1, it was observed from the image of Scanning Electron Microscope that the particle sizes of the polydisperse large-particle-size silica sol were distributed between 20 nm and 85 nm; the average particle size measured by a Laser Particle Size Analyzer (dynamic light scattering method) was 78.9 nm, the pH value was 9.96, and the concentration was 22.4 wt %.

### Example 2: Polydisperse Large-Particle-Size Silica Sol and Method of Preparing the Same

Step (2): take a 0.3 wt % sodium hydroxide solution with a volume of 1500 ml, stir and heat the solution to 100° C.; pump 3500 ml of the active silicic acid prepared in step (1) through a peristaltic pump at a rate of 3.5 ml/min. After the addition of the active silicic acid was completed, preserve the temperature for 1.5 hours. Naturally cool it to the room temperature, thereby obtaining the monodisperse small-particle-size spherical silica sol with a particle size of 20 nm-30 nm as a crystal seed.

Step (3), weigh 1000 ml of the crystal seed prepared in step (2) as mother solution, stir and heat the solution to boil the solution; add the active silicic acid prepared in step (1) at a rate of 5.8 ml/min through the peristaltic pump, and meanwhile continuously supplement 3847 ml of the crystal seed prepared in step (2) through the peristaltic pump at a rate of 1 ml/min during the whole addition process of the active silicic acid; during this period of time, drop a 1 wt % sodium hydroxide diluted solution to maintain the pH value of the whole system between 9.50 and 10.50. After the reaction was completed, preserve the temperature at 100° C. for 0.5 hours; naturally cool it to the room temperature; derive polydisperse large-particle-size silica sol spherical silica sol.

As illustrated in FIG. 2, it was observed from the image of Scanning Electron Microscope that the particle sizes of the polydisperse large-particle-size silica sol were distributed between 20 nm and 95 nm; the average particle size measured by a Laser Particle Size Analyzer (dynamic light scattering method) was 82.2 nm, the pH value was 10.10, and the concentration was 20.41 wt %.

### Example 3: Polydisperse Large-Particle-Size Silica Sol and Method of Preparing the Same

Step (1): Dilute concentrated water glass with pure water to a 6% content of silicon oxide; stir it evenly, and then add it into a strong acid-type cation exchange resin (polyphenyl sulfonic acid-type) that has been subject to regeneration processing, for cation exchanging; thereby obtaining an active silicic acid with a pH value of 2.74.

Step (2): take a 0.3 wt % sodium hydroxide solution with a volume of 1500 ml, stir and heat to 100° C.; pump 3500 ml of the active silicic acid prepared in step (1) through a peristaltic pump at a rate of 3.5 ml/min. After the addition of the active silicic acid was completed, preserve the temperature for 2 hours. Naturally cool it to the room temperature and thereby the monodisperse small-particle-size spherical silica sol with a particle size of 20 nm-30 nm as a crystal seed.

Step (3), weigh 800 ml of the crystal seed prepared in step (2) as mother solution, stir and heat the solution to boil the solution; use the peristaltic pump to add the active silicic acid prepared in step (1) at a rate of 4.4 ml/min; and meanwhile continuously supplement 9969 ml of the crystal seed prepared in step (2) through the peristaltic pump at a rate of 1.85 ml/min during the whole addition process of the silicic acid; during this period of time, drop a 2 wt % mixed diluted solution of sodium hydroxide and potassium hydroxide to maintain the pH value of the whole system between 9.50 and 10.50. After the reaction was completed, preserve the temperature at 100° C. for 1.2 hours; naturally cool it to the room temperature; thereby obtaining the polydisperse large-particle-size silica sol spherical silica sol.

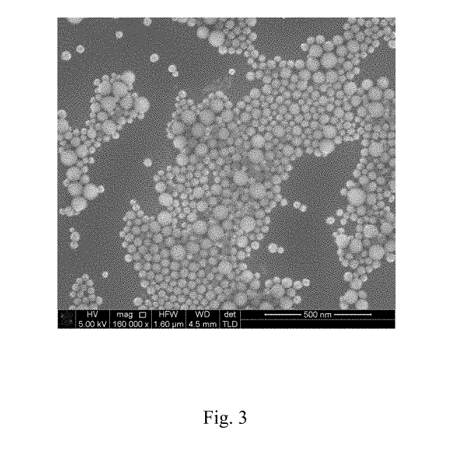

As illustrated in FIG. 3, it was observed from the image of Scanning Electron Microscope that the particle sizes of the polydisperse large-particle-size silica sol were distributed between 20 nm and 85 nm; the average particle size measured by a Laser Particle Size Analyzer (dynamic light scattering method) was 68.4 nm, the pH value was 10.32, and the concentration was 30.90 wt %.

### Example 4: Silica Sol Polishing Experiment

The polydisperse large-particle-size silica sol prepared in Examples 1-3 was configured into polishing solution for roughly polishing a sapphire sheet.

Method of configuring the polishing solution: dilute the polydisperse large-particle-size silica sol prepared by the present disclosure using pure water to a 15 wt % content of the silicon oxide, use a 5 wt % sodium hydroxide water solution to adjust the pH value to 10.50; stir the solution evenly, then weigh 1 kg of the solution, which is the resulting polishing solution.

Polishing experiment: attach 2-inch C-phase sapphire sheet onto a polishing head through a back film absorption method. The polishing parameters were provided below: the polishing pressure was 6 psi; the rotation speed of the polishing pad was 100 rpm; the rotation speed of the polished wafer was 90 rpm; the flow rate of the polishing solution was 125 ml/min; the polishing time was 30 min. Each time after the polishing was completed, use the 4-inch diamond repairing disc to repair the polishing pad for 5 minutes; the polished sapphire sheet was ultrasonically washed in the washing liquid for 10 minutes and then blown dry using nitrogen gas. A metallographic microscope was used to observe the surface quality condition of the polished sapphire sheet. By measuring the quality difference before and after the sapphire sheet was polished, the polishing rate was calculated. The results are shown in Table 1 below.

What is claimed is:

1. A method of preparing a polydisperse large-particle-size silica sol, comprising: stirring and heating a monodisperse spherical silica sol with a particle size between 20 nm-30 nm, the monodisperse spherical silica sol being taken as a crystal seed; and meanwhile constantly dropping the crystal seed of the monodisperse spherical silica sol with a particle size between 20 nm-30 nm and active silicic acid into a reaction system; during a whole reaction procedure, maintaining a constant liquid level by using a heating concentration method and meanwhile, dropping inorganic alkaline solution to maintain a pH value of the system between 9.5 and 10.5; and preserving the temperature upon end of the reaction and cooling it.

2. The method of preparing a polydisperse large-particle-size silica sol according to claim 1, wherein the preparing method further comprises steps of:
Step (1) of preparing active silicic acid: adding a water glass solution with a silicon oxide content of 2-6 wt % into a strong acid-type cation exchange resin for cation exchanging, to obtain an active silicic acid with a pH between 2.0 and 4.0;
Step (2) of preparing a monodisperse small-particle-size silica sol crystal seed: taking an inorganic alkali solution of 0.1-1.0 wt %, stirring and heating it to 90-100° C.; gradually adding the active silicic acid prepared in the step (1) with a volume 2-4 times than that of the inorganic alkali solution; after the addition is completed, continuing to preserve the temperature, and cooling it to the room temperature, to obtain the monodisperse spherical silica sol with the particle size between 20 nm and 30 nm as the crystal seed;
Step (3) of preparing polydisperse large-particle-size silica sol: taking the crystal seed prepared in step (2) as mother solution; stirring and heating it to be boiled; then dropping the active silicic acid prepared in the step (1) into the reaction system with a rate of 4-10 ml/min;
meanwhile, continuously and constantly supplementing the crystal seed prepared in the step (2) into the reaction system at a rate of 0.85-1.85 ml/min, wherein the constant liquid level is maintained and the inorganic alkali solution is added so as to maintain the pH value of the whole system at 9.50-10.50; upon completion of the adding, continuing to preserve temperature, and naturally cooling it to the room temperature.

3. The method of preparing a polydisperse large-particle-size silica sol according to claim 1, wherein the cation exchange resin used in the step (1) is a cation exchange resin which has been subjected to regeneration processing.

4. The method of preparing a polydisperse large-particle-size silica sol according to claim 1, wherein a duration for which the temperature is preserved in the step (2) is 0.5-2 hours.

5. The method of preparing a polydisperse large-particle-size silica sol according to claim 1, wherein a speed at which the active silicic acid is added in the step (2) is 2-20 ml/min.

6. The method of preparing a polydisperse large-particle-size silica sol according to claim 1, wherein a duration for which the temperature is preserved in the step (3) is 0.5-2 hours.

7. The method of preparing a polydisperse large-particle-size silica sol according to claim 1, wherein the alkali solution in the step (3) is selected from any one of potassium hydroxide solution and sodium hydroxide solution, or a mixture thereof.

8. A polydisperse large-particle-size silica sol prepared using the method of preparing a polydisperse large-particle-size silica sol according to claim 1.

9. A polydisperse large-particle-size silica sol prepared using the method of preparing a polydisperse large-particle-size silica sol according to claim 2.

10. A polydisperse large-particle-size silica sol prepared using the method of preparing a polydisperse large-particle-size silica sol according to claim 3.

11. A polydisperse large-particle-size silica sol prepared using the method of preparing a polydisperse large-particle-size silica sol according to claim 4.

12. A polydisperse large-particle-size silica sol prepared using the method of preparing a polydisperse large-particle-size silica sol according to claim 5.

13. A polydisperse large-particle-size silica sol prepared using the method of preparing a polydisperse large-particle-size silica sol according to claim 6.

14. The polydisperse large-particle-size silica sol according to claim 8, wherein a particle size of the polydisperse large-particle-size silica sol is distributed over a range of 20 nm-95 nm.

15. Usage of a polydisperse large-particle-size silica sol according to claim 8 for preparing a polishing solution.
